(19) United States
(12) Patent Application Publication
(10) Pub. No.: US 2025/0218827 A1
(43) Pub. Date: Jul. 3, 2025

(54) END POINT DETECTION DEVICE, ETCHING CONTROL SYSTEM, END POINT DETECTION METHOD, AND END POINT DETECTION PROGRAM

(71) Applicant: HORIBA STEC, Co., Ltd., Kyoto (JP)

(72) Inventors: Michie IMANISHI, Kyoto (JP); Miyako HADA, Kyoto (JP); Yuhei SAKAGUCHI, Kyoto (JP); Masakazu MINAMI, Kyoto (JP); Motonobu TAKAHASHI, Kyoto (JP)

(73) Assignee: HORIBA STEC, Co., Ltd., Kyoto (JP)

(21) Appl. No.: 18/999,366

(22) Filed: Dec. 23, 2024

(30) Foreign Application Priority Data
Dec. 28, 2023 (JP) 2023-222427

(51) Int. Cl. H01L 21/67

(52) U.S. Cl. CPC H01L 21/67253; H01L 21/67069

(57) ABSTRACT

An end point detection device that detects an end point in etching processing of a multilayer film, includes a measurement unit that measures a physical quantity that changes with the etching processing, an end point detection unit that detects an end point in a target film for which the end point is to be detected using a predetermined detection algorithm based on a measurement value obtained by the measurement unit, and an algorithm change unit that changes the detection algorithm in the film that is being subjected to the etching processing based on the measurement value obtained by the measurement unit when another film of a same type as the target film was being subjected to the etching processing in a same multilayer film as the target film currently being etching processed.

### CLAIM FOR PRIORITY

This application claims the priority benefit of Japanese application 2023-222427 filed Dec. 28, 2023, the entire contents of which is expressly incorporated by reference herein in its entirety.

### BACKGROUND OF THE INVENTION

### 1. Technical Field

The present invention relates to an end point detection device, an etching control system, an end point detection method, and an end point detection program.

### 2. Description of the Related Art

In a case where a semiconductor wafer is subjected to etching processing in a semiconductor manufacturing process, a technique for stopping the etching processing at a desired depth becomes more important. This is because surface roughness of a film after the etching processing greatly affects characteristics of a semiconductor device. Further, a technique for detecting an end point in the etching processing in real time is required for improving a yield ratio.

In particular, in a wafer having a multilayer film (hereinafter, a multilayer film wafer), the same wafer is deepened, and thus, it becomes more difficult to detect the end point as the depth increases and an aperture ratio decreases.

Here, as in Patent Document 1, a method of determining an end point of etching processing by measuring temporal change of plasma emission intensity from an etching processing chamber using optical emission spectroscopy is considered.

However, there are a non-plasma process that cannot be measured using optical emission spectroscopy, decrease in emission intensity caused by decrease in an aperture ratio, decrease in an etching rate accompanying increase in an etching depth, and the like, and thus, there is a case where the end point cannot be obtained with high accuracy using optical emission spectroscopy.

### PRIOR ART DOCUMENT

### Patent Document

JP 2001-7084 A

### SUMMARY OF THE INVENTION

Thus, the present invention has been made to solve the above-described problem, and it is an object of the present invention to perform etching processing of a multilayer film with high accuracy by accurately obtaining an end point.

In other words, an end point detection device according to the present invention is an end point detection device that detects an end point in etching processing of a multilayer film, and includes a measurement unit that measures a physical quantity that changes with the etching processing, an end point detection unit that detects an end point in a target film for which the end point is to be detected using a predetermined detection algorithm based on a measurement value obtained by the measurement unit, and an algorithm change unit that changes the detection algorithm in a film that is being subjected to the etching processing based on the measurement value obtained by the measurement unit when another film of the same type as the target film that is being subjected to the etching processing in the same multilayer film as the target film has been previously subjected to the etching processing.

According to such an end point detection device, the detection algorithm of the end point in the film that is being subjected to the etching processing in the multilayer film is changed based on the measurement value obtained by the measurement unit when another film of the same type as the target film that is being subjected to the etching processing in the same multilayer film as the target film has been previously subjected to the etching processing, so that the end point in the film that is being subjected to the etching processing can be obtained with high accuracy. This results in making it possible to perform the etching processing of the multilayer film with high accuracy.

As a specific aspect of the algorithm change unit, the algorithm change unit preferably changes the detection algorithm of the end point in the film that is being subjected to the etching processing based on past two or more measurement values obtained by the measurement unit when another film of the same type as the target film that is being subjected to the etching processing in the same multilayer film as the target film has been previously subjected to the etching processing.

According to this configuration, it is possible to change the detection algorithm of the end point in the film that is being subjected to the etching processing to an optimum one by using the past two or more measurement values.

As a specific aspect of the algorithm change unit, the algorithm change unit preferably changes a detection threshold of the end point in the film that is being subjected to the etching processing.

As a specific aspect of the end point detection unit, the end point detection unit preferably calculates a transition period between a transition start point and a transition end point during which a film that is being subjected to the etching processing transitions from the film that is being subjected to the etching processing to a next film.

The end point detection device according to the present invention preferably further includes a data storage unit that stores relationship data indicating a relationship between a transition period between a transition start point and a transition end point in the measurement value obtained by the measurement unit when another film of the same type as the target film that is being subjected to the etching processing in the same multilayer film as the target film has been previously subjected to the etching processing and a slope of the measurement value between the transition start point and the transition end point, and the end point detection unit preferably calculates the transition period for transition from the film that is being subjected to the etching processing to the next film based on the relationship data and the slope immediately after the transition start point in the film that is being subjected to the etching processing.

According to this configuration, even in a case where a film thickness of the film that is being subjected to the etching processing is different from a film thickness of the same type of the film that has been subjected to the etching processing, the transition period for transition from the film that is being subjected to the etching processing to the next film can be obtained with high accuracy.

The end point detection device according to the present invention preferably further includes a display control unit that displays time-series change in the measurement value obtained by the measurement unit on a display.

According to this configuration, as a result of the time-series change of the measurement value being displayed on the display, a user can use the time-series change as a reference when the user changes an etching recipe.

As a specific aspect of the measurement unit, the measurement unit preferably performs absorption measurement of a reaction product generated by the etching processing. For example, by measuring the reaction product generated by the etching processing using absorption spectroscopy, the end point can be detected even in a non-plasma process that cannot be measured using optical emission spectroscopy as in the related art.

Further, an etching control system according to the present invention includes an etching control device that controls an etching processing device that performs etching processing on a multilayer film, and the end point detection device described above. When a transition start point indicating start of transition from the film that is being subjected to the etching processing to the next film is detected by the end point detection device, the etching control device preferably changes an etching recipe in the film that is being subjected to the etching processing in the multilayer film.

According to this etching control system, after the transition start point indicating the start of the transition of the film that is being subjected to the etching processing from the film that is being subjected to the etching processing to the next film is detected, the etching recipe in the film that is being subjected to the etching processing is changed, so that an optimum recipe can be made and the etching processing can be performed with high accuracy.

The etching control device preferably changes an etching rate of the film that is being subjected to the etching processing in the multilayer film. Here, changing the etching rate includes, for example, adjusting a flow rate of a reactive gas to be introduced into a process chamber for etching processing, changing plasma power to be generated in the process chamber, or changing a temperature (reaction temperature) of an object (for example, a wafer) that is being subjected to the etching processing.

Furthermore, an end point detection method according to the present invention is an end point detection method for detecting an end point in etching processing of a multilayer film, and includes measuring, by a measurement unit, a physical quantity that changes with the etching processing, detecting an end point in a target film for which the end point is to be detected using a predetermined detection algorithm based on a measurement value obtained by the measurement unit, and changing the detection algorithm in a film that is being subjected to the etching processing based on the measurement value obtained by the measurement unit when another film of the same type as the target film that is being subjected to the etching processing in the same multilayer film as the target film has been previously subjected to the etching processing.

In addition, an end point detection program according to the present invention is a program to be used in an end point detection device that detects an end point in etching processing of a multilayer film, and causes a computer to include a function as a reception unit that receives measurement value data from a measurement unit that measures change associated with the etching processing, a function as an end point detection unit that detects an end point in a target film for which the end point is to be detected using a predetermined detection algorithm based on a measurement value obtained by the measurement unit, and a function as an algorithm change unit that changes the detection algorithm in a film that is being subjected to the etching processing based on the measurement value obtained by the measurement unit when another film having the same composition as the target film that is being subjected to the etching processing in the same multilayer film as the target film has been previously subjected to the etching processing.

Note that the end point detection program may be distributed electronically or may be recorded in a program recording medium such as a CD, a DVD, or a flash memory. Further, the end point detection program may be incorporated in a mother board of a device body.

As described above, according to the present invention, the etching processing of the multilayer film can be performed with high accuracy by accurately obtaining the end point.

### BRIEF DESCRIPTION OF THE DRAWINGS

FIG. 1 is a view schematically illustrating a configuration of an etching control system according to one embodiment of the present invention;

FIG. 2 is a cross-sectional view schematically illustrating a substrate having a multilayer film structure according to the embodiment;

FIG. 3 is a graph indicating time-series change in a measurement value of a measurement unit of the embodiment; and

FIG. 4 is a view indicating a measurement value of a first layer SiO film, a measurement value of a third layer SiO film, and a measurement value of a fifth layer SiO film (and values of first-order differentials) for indicating a method of calculating a transition period according to the embodiment.

### DETAILED DESCRIPTION

### One Embodiment of the Present Invention

Hereinafter, one embodiment of an etching control system incorporating an end point detection device according to the present invention will be described with reference to the drawings. Note that any of the drawings indicated below is illustrated while omission or exaggeration is performed as appropriate for easy understanding. The same components are denoted by the same reference numerals, and description thereof will be omitted as appropriate.

### <Device Configuration>

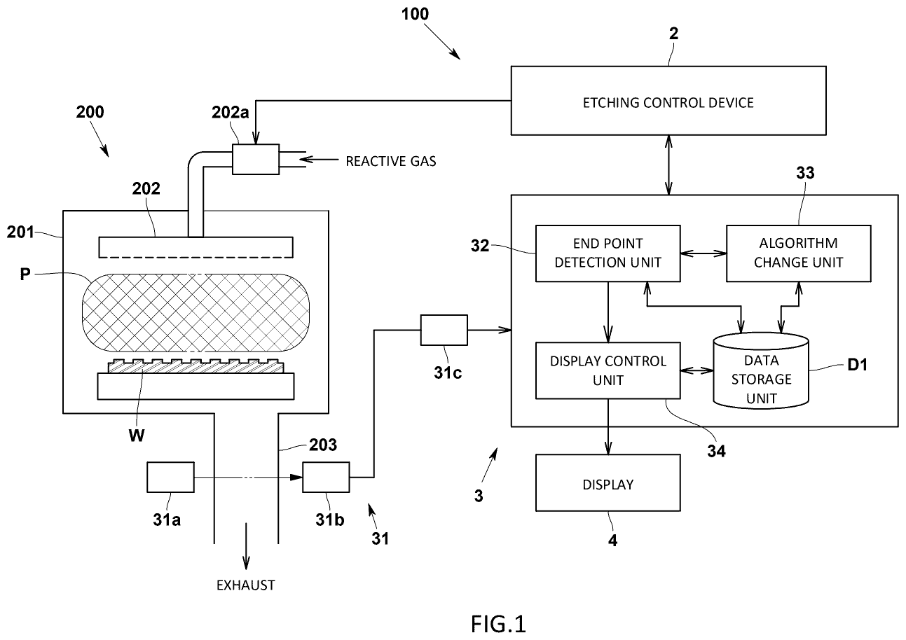

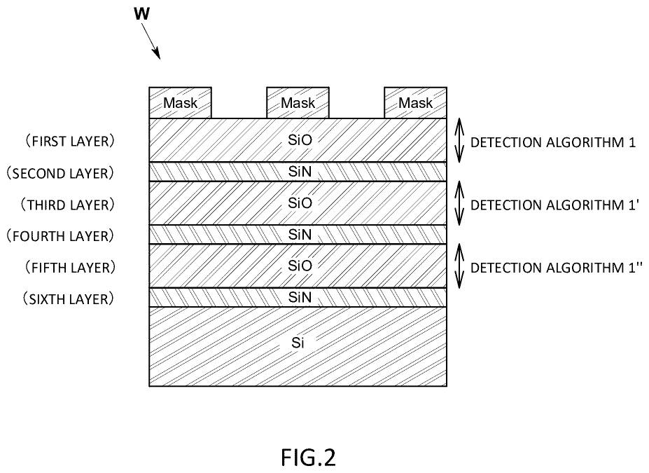

As illustrated in FIG. 1, an etching control system 100 of the present embodiment controls an etching processing device 200 for performing etching processing such as plasma etching. As illustrated in FIG. 2, an object W that is being subjected to the etching processing here is, for example, one in which a multilayer film structure is formed on a main surface of a silicon substrate, and as the multilayer film structure, two types of films (here, an SiO film and an SiN film) are alternately formed. Note that in the multilayer film structure, three or more types of films may be periodically formed.

In addition, the etching processing device 200 includes a process chamber 201 in which the etching processing is to be performed, a plasma generation mechanism (not illustrated) that generates plasma P in the process chamber 201, and a gas introduction mechanism 202 that introduces a reactive gas into the process chamber 201. The gas introduction mechanism 202 is provided with a flow rate adjustment mechanism 202a (for example, a mass flow controller) that adjusts a flow rate of the reactive gas to be introduced into the process chamber 201.

Specifically, as illustrated in FIG. 1, the etching control system 100 includes an etching control device 2 that controls the etching processing device 200 that performs etching processing on a multilayer film, and an end point detection device 3 that detects an end point in the etching processing of the multilayer film.

### <Etching Control Device 2>

The etching control device 2 etches the multilayer film by controlling the etching processing device 200.

Specifically, the etching control device 2 controls the etching processing device 200 based on a recipe set in advance for each film in the multilayer film and controls evacuation of the process chamber 201, plasma generation by the plasma generation mechanism, introduction of a reactive gas by the gas introduction mechanism 202, and the like, to control the etching processing of the multilayer film. The etching control device 2 can control an etching rate by controlling the flow rate adjustment mechanism 202a of the gas introduction mechanism 202.

### <End Point Detection Device 3>

The end point detection device 3 detects an end point in the etching processing of the multilayer film and detects transition from a film that is currently being subjected to the etching processing to the next film in the multilayer film.

Note that in the following embodiment, the end point is an end point of a transition period for transition from the film that is currently being subjected to the etching processing to the next film. Note that the end point may be artificially determined by comparing a signal obtained from the measurement unit 31 to be described later with an etching processing result. For example, a start point of the transition period may be set as the end point, or a midpoint of the transition period may be set as the end point.

Specifically, the end point detection device 3 includes a measurement unit 31 that measures a physical quantity that changes with the etching processing, and an end point detection unit 32 that detects an end point by changing a detection algorithm of the end point in the film that is currently being subjected to the etching processing in the multilayer film based on the measurement value obtained by the measurement unit 31.

The measurement unit 31 of the present embodiment measures a reaction product (by-product) generated by the etching processing using absorption spectroscopy. Specifically, the measurement unit 31 uses infrared laser absorption spectroscopy and includes a laser light source 31a that irradiates the process chamber 201 or an exhaust pipe 203 connected to the process chamber 201 with an infrared laser, a photodetector 31b that detects the infrared laser that has passed through the process chamber 201 or the exhaust pipe 203 connected to the process chamber 201, and a calculation unit 31c that calculates concentration or a partial pressure of a component to be measured using a light intensity signal of the photodetector 31b. Note that the measurement unit 31 of the present embodiment uses an infrared laser absorption modulation method (Japanese Patent No. 6886507), but may use other absorption spectrometric methods.

Here, the laser light source 31a is a semiconductor laser. Specifically, the laser light source is a quantum cascade laser (QCL), which is one type of the semiconductor laser, and oscillates a mid-infrared (2.5 to 25 μm) laser beam. The laser light source 31a can modulate (change) an oscillation wavelength by a given current (or voltage). Note that as long as the oscillation wavelength is variable, other types of laser may be used, and a temperature may be changed in order to change the oscillation wavelength.

Furthermore, the photodetector 31b may be, for example, a thermal photodetector such as a thermopile or may be a photodetector using a quantum photoelectric element such as HgCdTe, InGaAs, InAsSb, or PbSc.

The calculation unit 31c calculates an absorption signal (absorbance signal) of gas from the light intensity signal output from the photodetector 31b and extracts a feature amount from the absorption signal to calculate the concentration or the partial pressure of the component to be measured. The concentration or the partial pressure of the component to be measured calculated by the calculation unit 31c is output to the end point detection unit 32 and the algorithm change unit 33 as a measurement value. Note that the calculation unit 31c includes an analog electric circuit including a buffer, an amplifier, and the like, a digital electric circuit including a CPU, a memory, and the like, and an AD converter, a DA converter, and the like, that intervene between the analog/digital electric circuits.

Based on the measurement value obtained by the measurement unit 31, the end point detection unit 32 detects the end point in the target film for which the end point is to be detected using a predetermined detection algorithm and detects transition from the film that is currently being subjected to the etching processing to the next film in the multilayer film. Here, the end point detection unit 32 can detect the end point in the etching processing of the multilayer film based on the measurement value itself obtained by the measurement unit 31 or other parameters obtained based on the measurement value.

In addition, the algorithm change unit 33 changes the detection algorithm in the film that is currently being subjected to the etching processing based on the measurement value obtained by the measurement unit 31 when another film having the same composition as the target film that is currently being subjected to the etching processing in the same multilayer film as the target film has been previously subjected to the etching processing. Here, the algorithm change unit 33 can change the detection algorithm based on the measurement value itself obtained by the measurement unit 31 or parameters (such as, for example, a transition period, a slope of the measurement value, a value obtained by first-order differentiation of the measurement value, a value obtained by second-order differentiation of the measurement value) regarding the end point obtained based on the measurement value. Note that the same type of film refers to films having the same constituent components, crystal structures, and the like.

Here, the “measurement value obtained by the measurement unit 31 when . . . has been previously subjected to the etching processing” is a measurement value obtained by the measurement unit 31 when another film of the same type as the target film that is currently being subjected to the etching processing has been previously subjected to the etching processing in the multilayer film that is currently being subjected to the etching processing. For example, in a case where the film that is currently being subjected to the etching processing in the multilayer film is, for example, a fifth layer SiO film, the measurement value is a measurement value obtained by the measurement unit 31 when the first or third layer SiO film that is a layer above the fifth layer in the multilayer film has been previously subjected to the etching processing.

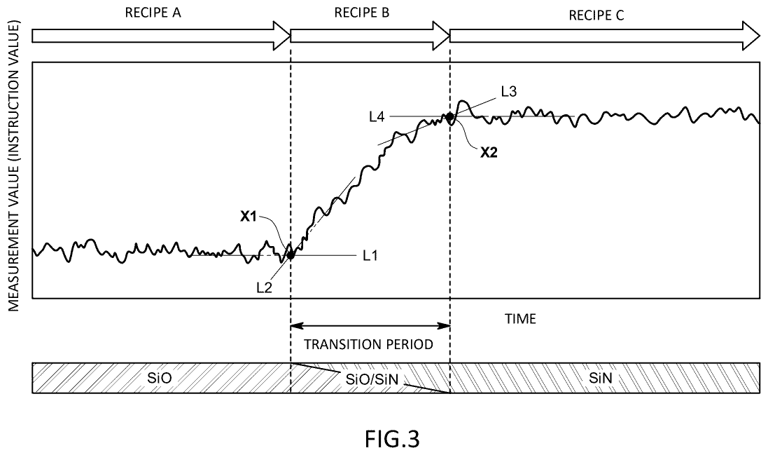

In addition, as indicated in FIG. 3, a detection method of the end point detection unit 32 of the present embodiment is performed by detecting a transition start point (first change point X1) and a transition end point (second change point X2) at which the film that is currently being subjected to the etching processing transitions to the next film in a time-series graph of the measurement value.

Specifically, as indicated in FIG. 3, the end point detection unit 32 detects the transition start point (first change point X1) using two regression lines L1 and L2 and detects the transition end point (second change point X2) using two regression lines L3 and L4. Here, by detecting the transition end point (second change point X2) by the end point detection unit 32, it can be determined that the etching processing of the film that is currently being subjected to the etching processing is completed.

Then, changing the detection algorithm of the end point detection unit 32 by the algorithm change unit 33 includes changing the parameters to be used for the detection method described above, and includes changing a period during which regression analysis is not performed on the end point, a period during which the regression analysis is performed on the end point, a confidence interval of a regression line, a period during which end point determination is not performed, a threshold of the measurement value, a detection threshold of the end point, a filter frequency, or the like.

### <Transition Period Calculation Method 1>

The end point detection unit 32 calculates a transition period for transition from the film that is currently being subjected to the etching processing to the next film based on past two or more measurement values obtained by the measurement unit 31 when another film of the same type as the film that is currently being subjected to the etching processing has been previously subjected to the etching processing. Note that in the following description, the film that is being subjected to the etching processing is an SiO film, but the same applies even if the film that is being subjected to the etching processing is an SiN film.

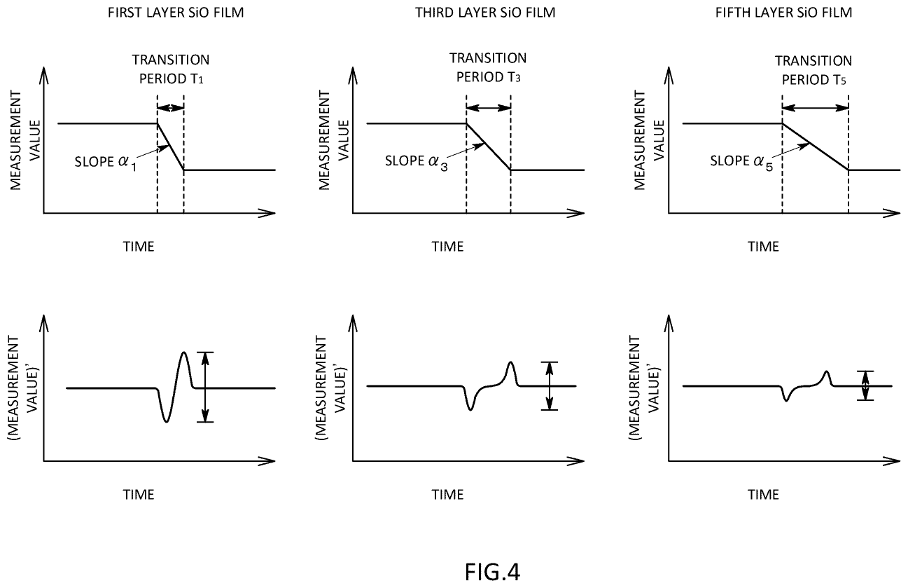

For example, as indicated in FIG. 4, in the multilayer film, in a case where the film that is currently being subjected to the etching processing is the fifth layer SiO film, the transition period of the fifth layer SiO film that is currently being subjected to the etching processing is calculated based on the measurement value obtained by the measurement unit 31 when the first layer SiO film has been subjected to the etching processing and the measurement value obtained by the measurement unit 31 when the third layer SiO film has been subjected to the etching processing. Note that the transition period is an elapsed period from a transition start point (here, the transition start point from the fifth layer to the sixth layer) to a transition end point (here, the transition end point from the fifth layer to the sixth layer).

Specifically, the transition period of the fifth SiO film can be calculated by obtaining a ratio between the transition period of the first SiO film and the transition period of the third SiO film. Note that in addition to the measurement value itself obtained by the measurement unit 31, a value obtained by performing first-order differentiation on the measurement value may be used, or a value obtained by performing second-order differentiation on the measurement value may be used.

For example, in a case where the transition period of the first layer SiO is T₁ and the transition period of the third layer SiO is T₃ (=T₁×k (coefficient)), the transition period T₅ of the fifth layer SiO can be obtained as T₅=T₃×k=T₁×k². As a result, the transition period T₅ of the fifth layer SiO can be calculated, and time to reach the end point can be predicted.

### <Transition Period Calculation Method 2>

In addition, the end point detection unit 32 calculates the transition period to transition from the film that is currently being etched to the next film based on a relationship between the transition period in the measurement value obtained by the measurement unit 31 when the same type of film as the film that is currently being etched has been previously etched and a slope of the measurement value therebetween, and a slope of the measurement value immediately after the transition start point in the film that is currently being etched.

Here, relationship data indicating a relationship between the transition period between the transition start point and the transition end point and the slope of the measurement value between the transition start point and the transition end point in the measurement value obtained by the measurement unit when the same type of film as the film that is currently being subjected to the etching processing has been previously subjected to the etching processing is stored in a data storage unit D1 (see FIG. 1). The relationship between the transition period and the slope of the measurement value in the present embodiment is a ratio (α/T) between the slope (α) of the measurement value during the transition period (T) and the transition period (T). Furthermore, the relationship data may be calculated by the end point detection unit 32 or may be calculated by an external calculation device.

For example, as indicated in FIG. 4, if the end point detection unit 32 detects a slope (α3) of the third layer SiO film immediately after the transition start point using a ratio (α₁/T₁) of the slope (α₁) of the transition period T₁ of the first layer SiO film to the transition period T₁ of the first layer SiO film, the transition period T₃ of the third layer SiO film can be obtained as T₃=(α₃/α₁)×T₁ from the detected slope (α₃) of the transition period T₃ of the third layer SiO film and the ratio (α₁/T₁) of the first layer SiO film. In addition, if a slope (α₅) of the fifth layer SiO film immediately after the transition start point is detected using a ratio (α₃/T₃) of the slope (α₃) of the transition period T₃ of the third layer SiO film to the transition period T₃, the end point detection unit 32 can obtain the transition period T₅ of the fifth layer SiO film from the detected slope (αs) of the transition period T₅ of the fifth layer SiO film and the ratio (α₃/T₃) of the third layer SiO film as T₅=(α₅/α₃)×T₃.

In addition, the end point detection device 3 may include the data storage unit D1 that stores time-series data of the measurement value of each layer obtained by the measurement unit 31, and a display control unit 34 that displays the time-series data of the measurement value of each layer on the display 4. The display control unit 34 can display not only the time-series data of the measurement value of each layer but also the data of the first-order differential or the second-order differential thereof and can also display the transition period calculated by the end point detection unit 32.

Note that the end point detection unit 32, the algorithm change unit 33, the display control unit 34, and the data storage unit D1 described above are constituted by a so-called computer including, for example, a CPU, a memory, an A/D and D/A converter, and an input/output unit. By executing an end point detection program stored in the memory and causing various devices to cooperate, the computer fulfills functions as the end point detection unit 32, the algorithm change unit 33, the display control unit 34, the data storage unit D1, and the like.

Then, if the end point detection device 3 detects the transition start point indicating start of transition from the film that is currently being subjected to the etching processing to the next film, the etching control device 2 can change the etching recipe in the film that is currently being subjected to the etching processing.

Specifically, it is conceivable that the etching control device 2 changes an etching rate of the film that is currently being subjected to the etching processing. In this event, the etching control device 2 controls the etching rate by controlling a flow rate adjustment mechanism 202a of the gas introduction mechanism 202. For example, it is conceivable that the etching control device 2 reduces the etching rate by controlling the flow rate adjustment mechanism 202a to reduce a flow rate of the reactive gas. In addition, it is conceivable to reduce the etching rate by changing plasma power to be generated in the process chamber. Furthermore, it is conceivable to reduce the etching rate by changing a temperature (reaction temperature) of an object (for example, a wafer) that is being subjected to the etching processing. In addition, the flow rate, or the like, of the reactive gas may be changed continuously or stepwise as the transition period elapses. Then, if the transition period in the film that is currently being subjected to the processing elapses, the etching control device 2 can stop the etching processing or change the recipe to a recipe corresponding to the next film.

### <Effects of Present Embodiment>

As described above, according to the etching control system 100 of the present embodiment, the detection algorithm of the end point in the film that is currently being subjected to the etching processing in the multilayer film is changed based on the measurement value obtained by the measurement unit 31 when another film of the same type as the film that is currently being subjected to the etching processing has been previously subjected to the etching processing, so that the end point in the film that is currently being subjected to the etching processing can be obtained with high accuracy. This results in making it possible to perform the etching processing of the multilayer film with high accuracy. In addition, the reaction product to be generated by the etching processing is measured using absorption spectroscopy, so that the end point can be detected even in a process in which a reaction product that cannot be measured using optical emission spectroscopy as in the related art is generated.

### Other Embodiments

For example, in the above embodiment, the end point detection device is incorporated in the etching control system, but the end point detection device does not have to be incorporated in the etching control system. In this case, the user may feed back data such as the transition period obtained by the end point detection device to the etching control device.

Furthermore, in a case where thicknesses of a plurality of films of the same type are different in the multilayer film, if a relationship between the film thicknesses and the etching rate is known in advance, the transition period, or the like, measured by the end point detection unit 32 can also be corrected based on the relationship.

Furthermore, in the above embodiment, the end point in the etching processing is detected, but the present invention can also be applied to detection of an end point of chamber conditioning such as cleaning of the process chamber 201.

The measurement unit 31 of the above embodiment uses absorption spectroscopy such as infrared laser absorption spectroscopy, but may use an optical measurement method such as optical emission spectroscopy or ICP optical emission spectroscopy. In addition, the measurement unit 31 may use mass spectrometry such as quadrupole mass spectrometry. In addition, the measurement unit 31 may measure a light emission amount or another physical quantity in addition to the light absorption intensity as long as the physical quantity that changes with the etching processing is measured.

In addition, various modifications and combinations of the embodiments may be made without departing from the gist of the present invention.

### REFERENCE SIGNS LIST

100 Etching control system
2 Etching control device
3 End point detection device
31 Measurement unit
32 End point detection unit
33 Algorithm change unit
34 Display control unit
D1 Data storage unit
4 Display

What is claimed is:

1. An end point detection device that detects an end point in etching processing of a multilayer film, the end point detection device comprising:
a measurement unit that measures a physical quantity that changes with the etching processing;
an end point detection unit that detects an end point in a target film for which the end point is to be detected using a predetermined detection algorithm based on a measurement value obtained by the measurement unit; and
an algorithm change unit that changes the detection algorithm in a film that is being subjected to the etching processing based on the measurement value obtained by the measurement unit when another film of a same type as the target film was being subjected to the etching processing in a same multilayer film as the target film currently being etching processed.

2. The end point detection device according to claim 1, wherein the algorithm change unit changes a detection threshold of the end point in the target film that is being subjected to the etching processing.

3. The end point detection device according to claim 1, wherein the end point detection unit calculates a transition period between a transition start point and a transition end point during which a film that is being subjected to the etching processing transitions from the film that is being subjected to the etching processing to a next film.

4. The end point detection device according to claim 1, wherein the algorithm change unit changes the detection algorithm of the end point in the film that is being subjected to the etching processing based on two or more past measurement values obtained by the measurement unit when another film of the same type as the target film was being subjected to the etching processing in the same multilayer film as the target film currently being etching processed.

5. The end point detection device according to claim 4, further comprising a data storage unit that stores relationship data indicating a relationship between a transition period between a transition start point and a transition end point in the measurement value obtained by the measurement unit when another film of the same type as the target film that is being subjected to the etching processing in the same multilayer film as the target film has been previously subjected to the etching processing and a slope of the measurement value between the transition start point and the transition end point,
wherein the end point detection unit calculates the transition period for transition from the film that is being subjected to the etching processing to the next film based on the relationship data and the slope of the measurement value immediately after the transition start point in the film that is being subjected to the etching processing.

6. The end point detection device according to claim 1, further comprising a display control unit that displays time-series change in the measurement value obtained by the measurement unit on a display.

7. The end point detection device according to claim 1, wherein the measurement unit performs absorption measurement of a reaction product generated by the etching processing.

8. An etching control system comprising:
an etching control device that controls an etching processing device that performs etching processing on a multilayer film; and
the end point detection device according to claim 1,
wherein when a transition start point indicating start of transition of the film that is being subjected to the etching processing from the film that is being subjected to the etching processing to a next film is detected by the end point detection device, the etching control device changes an etching recipe in the film that is being subjected to the etching processing in the multilayer film.

9. The etching control system according to claim 8, wherein the etching control device changes an etching rate of the film that is being subjected to the etching processing in the multilayer film.

10. An end point detection method for detecting an end point in etching processing of a multilayer film, the end point detection method comprising:
measuring, by a measurement unit, a physical quantity that changes with the etching processing;
detecting an end point in a target film for which the end point is to be detected using a predetermined detection algorithm based on a measurement value obtained by the measurement unit; and
changing the detection algorithm in a film that is being subjected to the etching processing based on the measurement value obtained by the measurement unit when another film of a same type as the target film was being subjected to the etching processing in a same multilayer film as the target film currently being etching processed.

11. A computer-readable medium including a program to be used in an end point detection device that detects an end point in etching processing of a multilayer film, the end point detection program causing a computer to include:
a function as a reception unit that receives measurement value data from a measurement unit that measures change associated with the etching processing;
a function as an end point detection unit that detects an end point in a target film for which the end point is to be detected using a predetermined detection algorithm based on a measurement value obtained by the measurement unit; and
a function as an algorithm change unit that changes the detection algorithm in the target film that is being subjected to the etching processing based on the measurement value obtained by the measurement unit when another film of a same type as the target film was being subjected to the etching processing in a same multilayer film as the target film currently being etching processed.
